(19) United States
(12) Patent Application Publication
(10) Pub. No.: US 2014/0355365 A1
(43) Pub. Date: Dec. 4, 2014

(54) PULSE GENERATOR

(71) Applicant: QUALCOMM Incorporated, San Diego, CA (US)

(72) Inventors: Changho Jung, San Diego, CA (US); Nishith Desai, San Diego, CA (US); Chulmin Jung, San Diego, CA (US)

(21) Appl. No.: 13/910,078

(22) Filed: Jun. 4, 2013

(51) Int. Cl. H03K 3/037; G11C 7/22

(52) U.S. Cl. CPC H03K 3/037; G11C 7/222
USPC 365/191; 327/299

(57) ABSTRACT

Various circuits and methods of operating circuits are disclosed. A circuit may include a pulse generator and a latch having an output configured to trigger the pulse generator, wherein the latch is configured to be set by an input signal and reset by feedback from the pulse generator. A method may include resetting a latch using feedback from a pulse generator by setting a latch using an input signal, triggering a pulse generator using an output from the latch, and resetting the latch using feedback from the pulse generator.

### BACKGROUND

1. Field

The present disclosure relates generally to electronic circuits, and more particularly, to a pulse generator for use with memory and other devices.

2. Background

A memory device is commonly used in many electronics devices, such as computers, wireless communication devices, personal digital assistants (PDAs), and other electronic devices. A memory device typically includes a large number of memory cells for storing data. A read circuit may be used to read data from the memory cells and a write circuit may be used to write data to the memory cells. The read circuit may include a pulse generator for generating a read clock. Similarly, the write circuit may include a pulse generator for generating a write clock. The read and write clocks are used to access the memory cells. The ability to properly access these memory cells often depends on the stability of the pulse generators used to generate the read and write clocks.

### SUMMARY

One aspect of a circuit includes a pulse generator and a latch having an output configured to trigger the pulse generator, wherein the latch is configured to be set by an input signal and reset by feedback from the pulse generator.

Another aspect of a circuit includes a generating means for generating a pulse, and a triggering means for triggering the generating means, wherein the triggering means is configured to be set by an input signal and reset by feedback from the generating means.

One aspect of a method includes setting a latch using an input signal, triggering a pulse generator using an output from the latch, and resetting the latch using feedback from the pulse generator.

It is understood that other aspects of apparatuses and methods will become readily apparent to those skilled in the art from the following detailed description, wherein various aspects of apparatuses and methods are shown and described by way of illustration. As will be realized, these aspects may be implemented in other and different forms and its several details are capable of modification in various other respects. Accordingly, the drawings and detailed description are to be regarded as illustrative in nature and not as restrictive.

### BRIEF DESCRIPTION OF THE DRAWINGS

Various aspects of apparatuses and methods will now be presented in the detailed description by way of example, and not by way of limitation, with reference to the accompanying drawings, wherein:

FIG. 1 is an architectural illustration of one example of a system comprising memory.

FIG. 2 is a block diagram illustrating one example of the memory.

FIG. 3 is a schematic representation of various components of the memory.

FIG. 4 is a schematic representation of one example of a replica circuit of the memory.

FIG. 5 is a schematic representation of one example of an access circuit of the memory.

FIG. 6 is a schematic representation of various circuits of the memory.

FIG. 7 is a flowchart illustrating one example of an operation performed by a circuit shown in FIG. 6.

### DETAILED DESCRIPTION

Various aspects of the disclosure will be described more fully hereinafter with reference to the accompanying drawings. This disclosure may, however, be embodied in many different forms by those skilled in the art and should not be construed as limited to any specific structure or function presented herein. Rather, these aspects are provided so that this disclosure will be thorough and complete, and will fully convey the scope of the disclosure to those skilled in the art. Based on the teachings herein, one skilled in the art should appreciate that the scope of the disclosure is intended to cover any aspect of this disclosure, whether implemented independently of or combined with any other aspect of the disclosure. For example, an apparatus may be implemented or a method may be practiced using any number of the aspects set forth herein. In addition, the scope of the disclosure is intended to cover such an apparatus or method which is practiced using other structure and/or functionality in addition to or instead of other aspects of this disclosure. It should be understood that any aspect of the disclosure disclosed herein may be embodied by one or more elements of a claim.

Although particular aspects will be described herein, many variations and permutations of these aspects fall within the scope of the disclosure. Although some benefits and advantages of the preferred aspects are mentioned, the scope of the disclosure is not intended to be limited to particular benefits, uses, or objectives. Rather, aspects of the disclosure are intended to be broadly applicable to different circuits, technologies, systems, networks, and methods, some of which are illustrated by way of example in the drawings and in the following description. The detailed description and drawings are merely illustrative of the disclosure rather than limiting, the scope of the disclosure being defined by the appended claims and equivalents thereof.

The various circuits described throughout this disclosure may be implemented in various forms of hardware. By way of example, any of these circuits, either alone or in combination, may be implemented as an integrated circuit, or as part of an integrated circuit. The integrated circuit may be an end product, such as a microprocessor, a digital signal processor (DSP), an application specific integrated circuit (ASIC), programmable logic, memory, or any other suitable integrated circuit. Alternatively, the integrated circuit may be integrated with other chips, discrete circuit elements, and/or other components as part of either an intermediate product, such as a motherboard, or an end product. The end product can be any suitable product that includes integrated circuits, including by way of example, a cellular phone, a personal digital assistant (PDA), a laptop computer, a desktop computer (PC), a computer peripheral device, a multimedia device, a video device, an audio device, a global positioning system (GPS), a wireless sensor, or any other suitable device.

Various aspects of pulse generators for use in read and write circuits in memory devices will now be presented. However, as those skilled in the art will recognize, these aspects may be extended to various other circuits used in memory and other devices. Examples of memory devices include random access memory (RAM), static RAM (SRAM), dynamic RAM (DRAM), synchronous dynamic RAM (SDRAM); double date rate RAM (DDRAM), read only memory (ROM), programmable ROM (PROM), erasable PROM (EPROM), electrically erasable PROM (EEPROM), a general register on a processor, flash memory, or any other suitable memory.

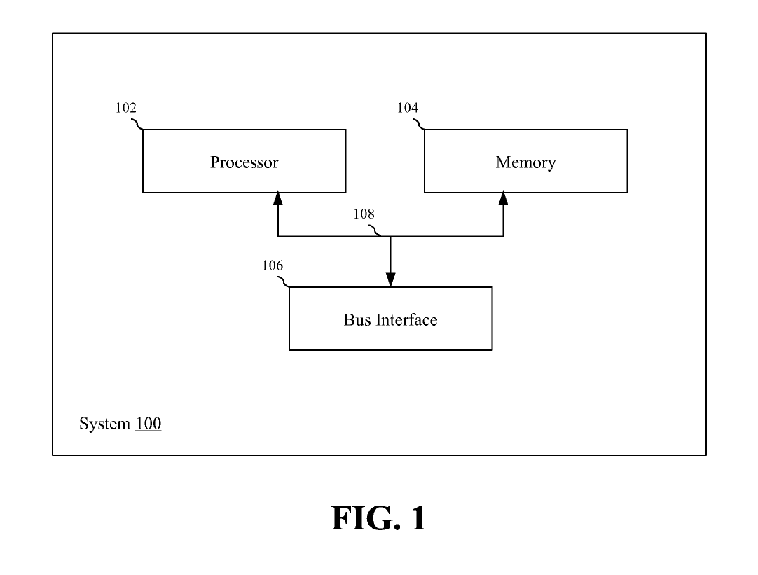

FIG. 1 is an architectural illustration of one example of a system 100 with memory 104 incorporating one or more pulse generators. The system 100 may include a processor 102 configured to retrieve and store program instructions and/or data in memory 104 over a bus 108. As used hereinafter, the term “data” will be understood to include program instructions, data, and any other information that may be stored in the memory 104. The bus 108 may be used to link together various circuits, including the processor 102, the memory 104, and a bus interface 106. The bus interface 106 may be configured to connect with other circuits located inside and/or outside of the system 100, such as timing sources, peripherals, voltage regulators, power management circuits, and the like.

In this example, the bus 108 may include three channels: an address channel, a write channel and a read channel. When writing to the memory 104, the processor 102 sends the address to the memory 104 on the address channel with a write enable complement signal. The data to be written to the memory 104 may be sent on the write channel. When reading from memory 104, the processor 102 sends the address to the memory 104 on the address channel with a read enable complement signal. In response, the memory 104 sends data to the processor 102 on the read channel. The enable signals may be sent with the address on the address channel, or alternatively, sent on a separate control channel on the bus 108 or by any other suitable means. As will be described in greater detail later, the enable signals may be used by one or more pulse generators in the memory 104 to generate read and write clocks to access the memory cells (not shown).

The memory 104 is shown as part of the system 100 but separate from the processor 102. However, as those skilled in the art will readily appreciate, the memory 104, or any portion thereof, may be external to the system 100. Alternatively, or in addition to, the memory 104, or any portion thereof, may be integrated into the processor 102, such as the case may be with cache and/or general register files, or distributed across multiple entities within or external to the system 100. Those skilled in the art will be best suited for determining the design of memory for any particular application based on the overall design constraints and any other relevant factors.

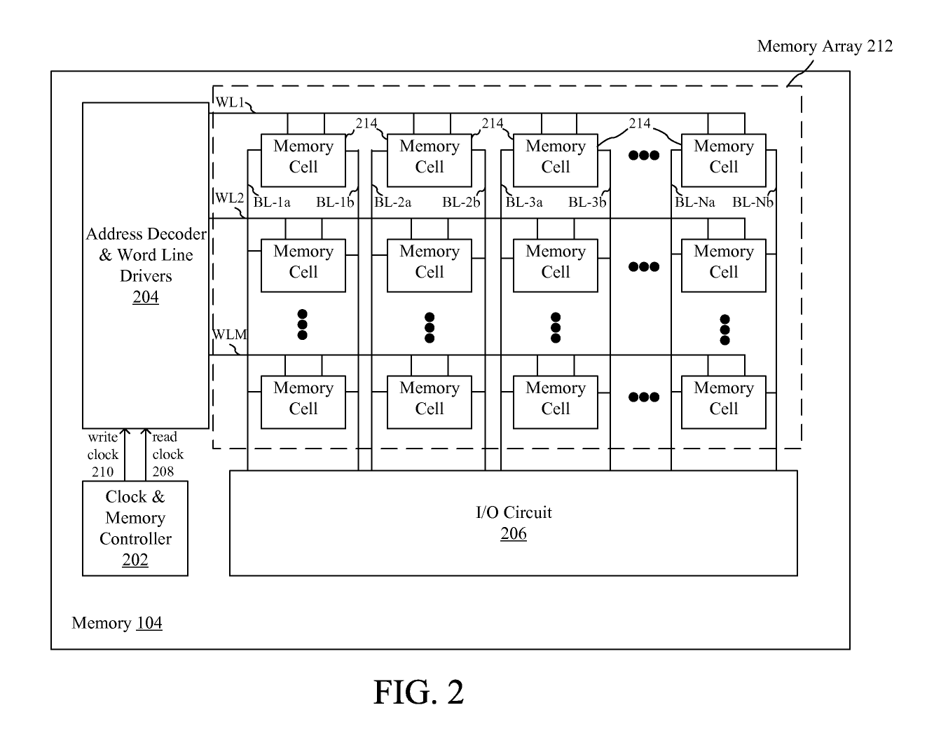

FIG. 2 is a block diagram illustrating one example of the memory 104. The memory 104 may include a clock & memory controller 202, a memory array 212 comprised of a large number of memory cells arranged in columns and rows, an address decoder and word line drivers 204, and an I/O circuit 206. As explained earlier, the processor 102 (see FIG. 1) may provide the address and control signals over the address channel of the bus 108 (see FIG. 1) to read and write from the memory 104. In the described embodiment, the address may be provided to the address decoder and word line drivers 204 and the enable signals may be provided to the clock & memory controller 202. However, as those skilled in the art will appreciate, the address and enable signals may be provided by other devices either external or internal to the memory 104.

The memory array 212 may include M number of rows and N number of columns of memory cells 214. In general, M and N may each have any value. The M rows of the memory cells 214 are selected via M word lines, which are depicted as word lines WL1 through WLM. The N columns of the memory cells 214 are coupled to N number of differential bit lines BL-1a and BL-1b thorough BL-Na and BL-Nb. The address decoder & word line drivers 204 may be used to decode the address transmitted by the processor 102 (see FIG. 1) on the address channel of the bus 108 (not shown) to activate the appropriate word and bit lines to access the desired memory cells 214.

The I/O circuit 206 may include various circuits for reading data from the memory cells 214 and writing data to the memory cells 214. For example, the I/O circuit 206 may include a sense amplifier (not shown) and a data output buffer (not shown) for reading data from the memory cells 214 and transmitting the data to the processor 102 (see FIG. 1) over the read channel of the bus 108 (not shown). The I/O circuit 206 may further include a data latch (not shown) and data input drivers (not shown) for receiving data from the processor 102 (see FIG. 1) over the write channel of the bus 108 (not shown) and writing the data to the memory cells 214.

The clock & memory controller 202 may use the enable signals transmitted by the processor 102 (not shown) for read and write operations of the memory array 212. More specifically, in the response to the enable signals, the clock & memory controller 202 may generate a write clock 210 to initiate a write operation and a read clock 208 to initiate a read operation. As will be explained in greater detail later, the read and write clocks 208, 210, respectively, may be used by the address decoder & word line drivers 204 to access the memory cells 214.

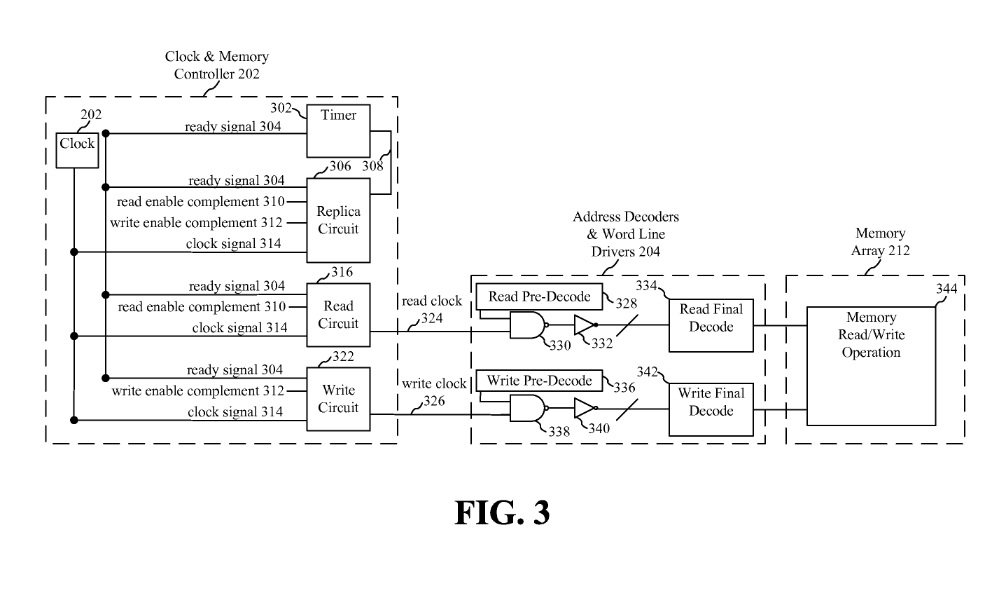

FIG. 3 is a schematic representation of various components of the memory 104, including the clock & memory controller 202, the address decoders & word line drivers 204, and the memory array 212. The clock & memory controller 202 may generate its own clock signal 314 from a clock 202 as shown, or alternatively, the clock signal may be provided from an external source. The clock signal 314 may be provided to a replica circuit 306 and access circuits in the clock & memory controller 202. In this example, the access circuits include a read circuit 316 that is used to generate a read clock 324 in response to a read enable complement signal 310 and a write circuit 322 that is used to generate a write clock 326 in response to a write enable complement signal 312. As will be explained in greater detail shortly, the read and write clocks 324, 326 are used to enable the address decoders & word line drivers 204 and ultimately access the memory array 212.

The access time for a read or write operation may vary depending on a number of factors, including by way of example, process variations during the manufacturing process. The replica circuit 306 and a timer 302 may be used to ensure that read and write clocks remain asserted for a sufficient amount of time to access the memory array. The replica circuit 306 is used to generate a replica clock 308 that replicates read and write clocks 324, 326. The replica clock 308 is used to trigger the timer 302. The timer 302 may have a timed output (e.g., ready signal 304) that is triggered by a pulse generator (of, e.g., the replica circuit 306). The timer 302 may reset the pulse generator at an end of the timed output. The timer 302 may include a large number of dummy memory cells that are arranged to emulate the memory cells in the memory array 212. The dummy memory cells allow the timer 302 to track the access time of the memory 212 represented by a ready signal 304 once the access time is satisfied. The ready signal 304 may be used to reset the read and write clocks 324, 326, along with the replica clock 308.

The address decoders and word line drivers 204 may be used to decode the address transmitted by the processor 102 over the bus 108 (see FIG. 1) in response to the read and write clocks 324, 326. In the embodiment shown, the decoding of the address is performed in two stages: a pre-decode stage and a final decode stage. However, those skilled in the art will readily appreciate that the decoding of the address may be done with a single stage decoding process.

The pre-decode stage includes a read pre-decode 328 representing the pre-decoded address transmitted by the processor 102 on the address channel of the bus 108 (see FIG. 1). The output from the read pre-decode 328 is gated by logic comprising a NAND gate 330 and inverter 332. The logic functions to pass the pre-decoded address to the input of the read final decode 334 when the read clock 324 is active. The read final decode 334 is used to drive the appropriate word lines and pre-charge the appropriate bit lines to read from the desired memory cells in the memory array 212.

The pre-decode stage also includes a write pre-decode 336 representing the pre-decoded address transmitted by the processor 102 on the address channel of the bus 108 (see FIG. 1). The output from the write pre-decode 336 is gated by logic comprising a NAND gate 338 and inverter 340. The logic functions to pass the pre-decoded address to the input of the write final decode 342 when the write clock 326 is active. The write final decode 342 is used to assert the appropriate word lines while the appropriate bit lines are driven to the appropriate state by the I/O circuit 206 (see FIG. 2).

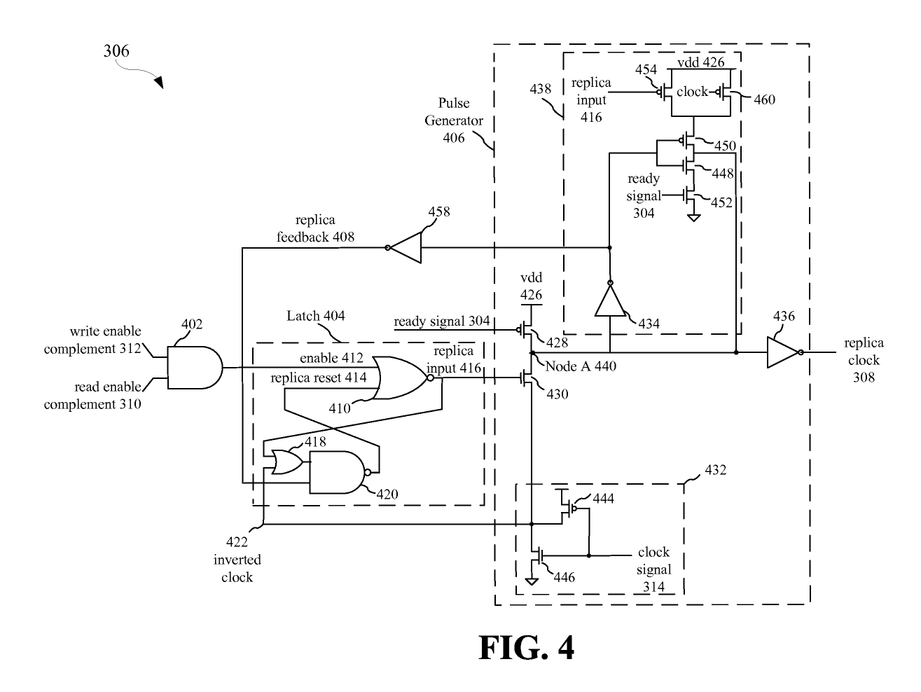

FIG. 4 is a schematic representation of one example of the replica circuit 306. The replica circuit 306 may include a pulse generator 406 which provides a means for generating a pulse. The pulse generator 406 generates the replica clock 308. In this example, the pulse generator 406 includes a transistor pair comprising p-channel transistor 428 and n-channel transistor 430. The transistors work together to pull down node A 440 to ground through a clock circuit 432 in response to an input 416 applied to the gate of the n-channel transistor 430 and pull up node A 440 to V_{dd} 426 in response to a ready signal 304 applied to the gate of the p-channel transistor 428. The clock circuit 432 may comprise pull-up transistor 444 and pull-down transistor 446. The output from node A 440 is provided to an inverter 436 that is used to drive the replica clock 308.

The latch 404 provides a means for triggering the pulse generator 406. The replica input 416 is set by the latch 404 when an enable 412 is captured on the clock edge. The replica input 416 is reset by the latch 404 in response to feedback from the pulse generator 406. The use of feedback from the pulse generator 406 to reset the replica input 416 ensures that the pulse width of the replica input 416 is adequate to enable node A 440 to sufficiently discharge to ground through the n-channel transistor 430 and the clock circuit 432. The use of feedback to reset the input 416 is preferred to using a fixed delay to control the timing of the replica input 416, which could result in undesirable race conditions resulting from process, voltage, and temperature (PVT) variations. By way of example, under certain PVT conditions, the replica input 416 controlled by a fixed delay could be reset before node A 440 is sufficiently discharged. In that case, the pulse generator 438 may fail to generate the replica clock 308.

In FIG. 4, the latch 404 may comprise a NOR gate 410 that is cross-coupled to an OR gate 418 and a NAND gate 420. The NOR gate 410 receives an enable 412 and a replica reset 414. The enable 412 is the output signal of AND gate 402, which receives the write enable complement 312 and the read enable complement 310. The read enable complement 310 is low when the read enable is high; otherwise, the read enable complement 310 is high. Similarly, the write enable complement 312 is low when the write enable is high; otherwise, the write enable complement 312 is high. The output of the NOR gate 410 is the replica input 416, which (among other things) is a first input of the OR gate 418. A second input of the OR gate is an inverted clock 422 signal. The output of the OR gate 418 is a first input of the NAND gate 420. A second input of the NAND gate 420 is the replica feedback 408. The replica feedback 408 is provided as the second input of the NAND gate 420. The replica reset 414 is output by the NAND gate 420 to the NOR gate 410.

Initially, the output from the latch 404 (i.e., the replica input 416 output from the NOR gate 410) is low. The low output from the NOR gate 410 is fed back to the input of the OR gate 418, which allows the inverted clock 422 signal from the clock circuit 432 to pass through the OR gate 418 to the input of the NAND gate 420. The replica feedback 408 from the pulse generator 406, which is initially high, is gated with the inverted clock 422 signal by the NAND gate 420. As long as the replica feedback 408 remains high, the output from the NAND gate 420 tracks the clock signal 314 input to the clock circuit 432. The output from the NAND gate 420 is provided to the NOR gate 410 as the replica reset 414.

When the read enable complement 310 or write enable complement 312 goes low, thereby forcing the enable 412 output from the AND gate 402 low, the replica input 416 output from the NOR gate 410 goes high with the falling edge of the replica reset 414. The replica input 416 passes through the OR gate 418 to the NAND gate 420, thereby enabling the NAND gate 420 to invert the replica feedback 408 from the pulse generator 406.

The replica input 416 is output from the latch 404 and provided to the input of the pulse generator 406. The replica input 416 turns on the n-channel transistor 430. When the clock signal 314 goes high, thereby turning on the n-channel transistor 446 in the clock circuit 432, node A 440 discharges to ground, which in turn forces the replica clock 308 output from the inverter 436 to be high. The transition from low to high of the inverter 436 output constitutes the leading edge of the replica clock 308.

Node A 440 is also fed back to the latch 404 through inverters 434, 458. The output from the inverter 458 is the replica feedback 408 which is provided to the NAND gate 420. With the output from the OR gate 418 high, the NAND gate 420 inverts the replica feedback 408 to generate the replica reset 414, which is fed back to the NOR gate 410. The replica reset 414, which is high, forces the output from the NOR gate 410 to be low. The output from the NOR gate 410, or the replica input 416, turns off the re-channel transistor 430 in the pulse generator 406, thereby disconnecting node A 440 from ground. Once disconnected, the low state of node A is maintained by a path to ground through transistors 448, 452 in the full keep circuit 438. The full keep circuit 438 is used to keep node A 440 from floating when both the p-channel transistor 428 and the n-channel transistor 430 are off.

As explained earlier in connection with FIG. 3, the rising edge of the replica clock 308 is used to trigger a timer 302 (see FIG. 3). The timer 302 provides a means for resetting the pulse generator 406. The timer 302 generates a ready signal 304 after a time delay that tracks the access time for the memory cells in the memory array 212 (see FIG. 3). Returning to FIG. 4, the ready signal 304, which in this example, is an inverted pulse, turns on the p-channel transistor 428 in the pulse generator 406 for the duration of the ready signal pulse width. Node A 440 is then pulled up to V_{dd} 426 through the p-channel transistor 428, which causes the replica clock 308 to transition from high to low. This transition constitutes the trailing edge of the replica clock 308.

Node A 440 is also fed back to the latch 404 through inverters 434, 458. The output from the inverter 458 is provided to the NAND gate 420 to reset the latch 404. When the replica feedback 408 is high and the replica input 416 output from the NOR gate 410 is low, the NAND gate 420 enters its initial state that was discussed above, where the inverted clock 422 signal is passed to the NOR gate 410 as the replica reset 414, thus allowing the latch 404 to capture the next read or write enable complement 310, 312 (see FIG. 3) on the rising edge of replica reset 414, which, as explained earlier, tracks the clock signal 314.

The full keep circuit 438 is used to keep node A 440 high once the n-channel transistor 428 is turned off following the ready signal 304 pulse. The full keep circuit 438 provides a path from V_{dd} 426 to node A 440 through transistors 454, 460, 450.

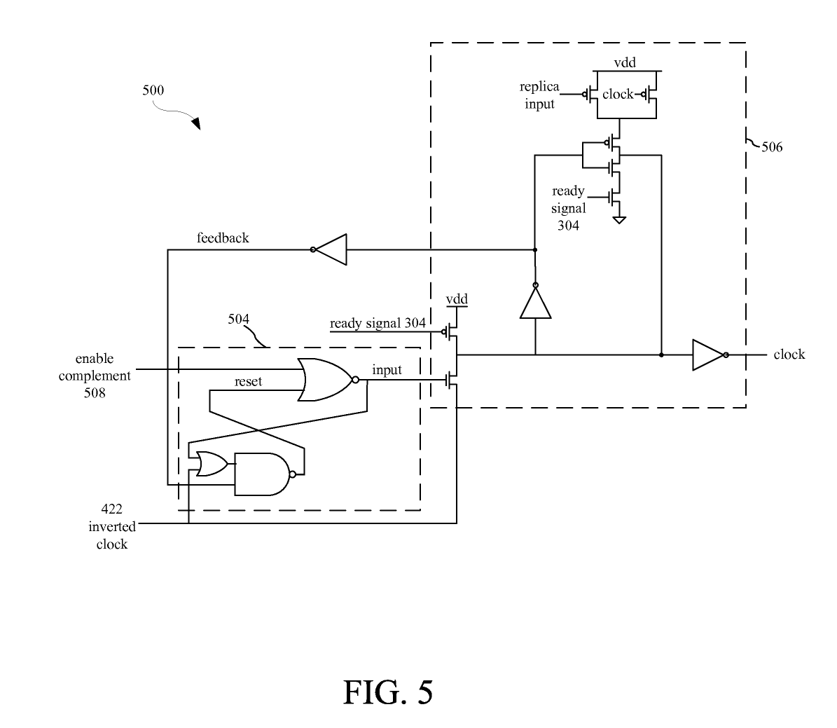

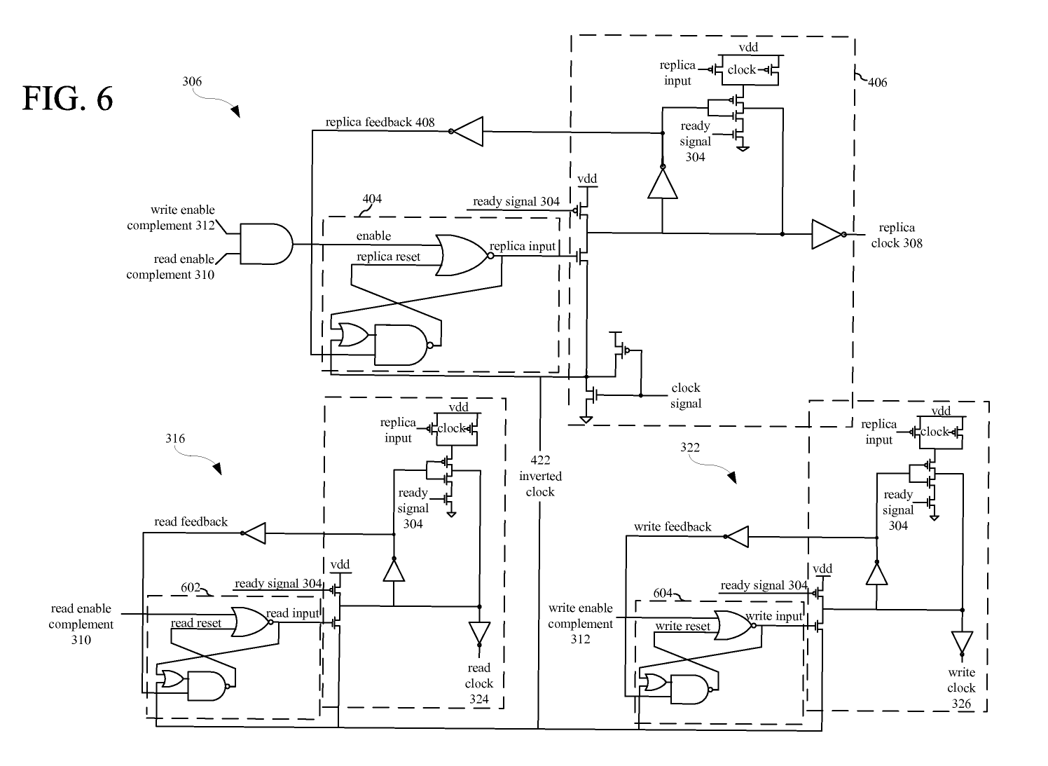

FIG. 5 is a schematic representation of an access circuit 500. The access circuit 500 may be a read circuit 316 or a write circuit 322 (see FIG. 6). The access circuit 500 is substantially the same as the replica circuit 306. The access circuit 500 includes a pulse generator 506 that provides a means for generating an output to control a word line and a latch 504 that provides a means to trigger the pulse generator 506. The primary difference between the access circuit 500 and the replica circuit 306 (see FIG. 4) is that only one enable complement signal (e.g., enable complement 508) is used to set the output of the latch 504. By way of example, if the access circuit 500 is a read circuit 316, the output of the latch 602 is set by the read enable complement 310 (see FIG. 6). If, on the other hand, the access circuit is a write circuit 322, the output of the latch 604 is set by the write enable complement 312 (see FIG. 6). As explained earlier in connection with FIG. 4, the output from the latch 404 in the replica circuit 306 is set by either the read enable complement 310 or the write enable complement 312 because the replica circuit 306 must be triggered during both the read and write operation to control the read clock 324 and the write clock 326, respectively (see FIG. 3).

In the embodiment shown in FIG. 5, the inverted clock 422 signal is provided from an external source. By way of example, the inverted clock 422 signal may be provided to the access circuit 500 by the replica circuit 306. Alternatively, the access circuit 500 may include its own clock circuit. Those skilled in the art will be readily able to determine the most suitable clock design depending on the particular application and the overall design constraints imposed on the system.

FIG. 6 is a schematic representation of various circuits in memory. In this example, the replica, read and write circuits 306, 316, 322 are shown. The clock circuit 432 in the replica circuit 306 (see FIG. 4) is used to provide an inverted clock 422 signal to both the read and write circuits 316, 322. As explained in greater detail earlier, the read enable complement 310 activates both the replica circuit 306 and the read circuit 316. In response to the read enable complement 310, the replica circuit 306 outputs a replica clock 308 and the read circuit outputs a read clock 324. The read clock 324 is provided to the address decoder and word line drivers 204 to read from the memory array 212 (see FIG. 3). The replica clock 308 is provided to a timer 302 that is used to generate a delay that tracks the access time for the memory array 212 (see FIG. 3). Following the delay, a ready signal 304 is generated by the timer 302 (see FIG. 3), which is used to reset both the replica clock 306 and the read clock 316.

In a similar manner, the write enable complement 312 activates both the replica circuit 306 and the write circuit 322. In response to the write enable complement 312, the replica circuit 306 outputs a replica clock 308 and the write circuit 322 outputs a write clock 326. The write clock 326 is provided to the address decoder and word line drivers 204 to write to the memory array 212 (see FIG. 3). The replica clock 308 is provided to a timer 302 that is used to generate a delay that tracks the access time for the memory array 212 (see FIG. 3). Following the delay, a ready signal 304 is generated by the timer 302 (see FIG. 3), which is used to reset the replica clock 308 and the write clock 326.

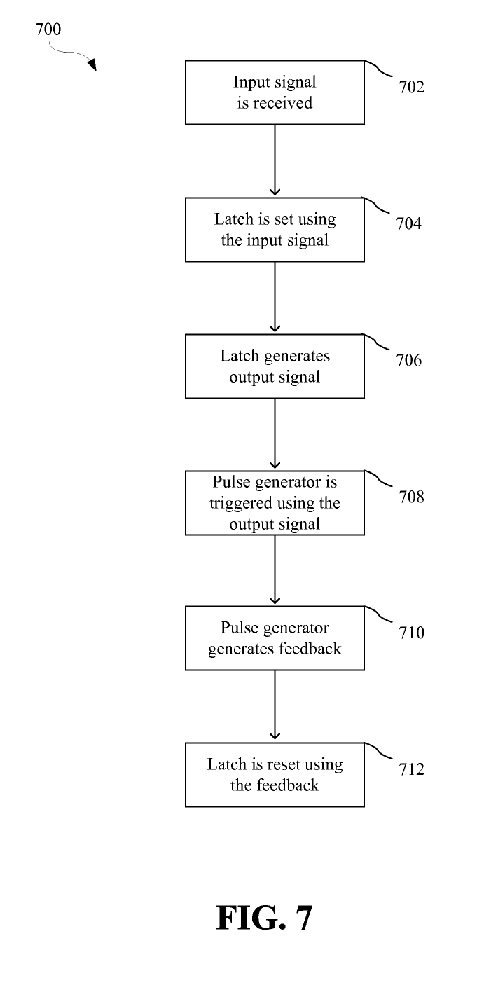

FIG. 7 is a flowchart illustrating one example of an operation performed by a circuit shown in FIG. 6. By way of example, a method 700 performed by a circuit may comprise receiving an input signal at block 702 and setting a latch using that input signal at block 704. Once the latch is set, the latch may generate an output signal at block 706. The generated output signal may trigger the pulse generator at block 708. Once the pulse generator is triggered, the pulse generator may generate feedback at block 710, wherein the generated feedback may serve as an input to a portion of the latch. Subsequently, the latch may be reset using the feedback at block 712.

The specific order or hierarchy of blocks in the processes disclosed in FIG. 7 is merely an illustration of on example. Based upon design preferences, the specific order or hierarchy of blocks in the process may be re-arranged, amended, and/or modified. The accompanying method claims include various limitations related to a process, but the recited limitations are not meant to be limited in any way by the specific order or hierarchy depicted in FIG. 7 unless expressly stated in the claims.

Although various aspects of the present invention have been described as software implementations, those skilled in the art will readily appreciate that the various software modules presented throughout this disclosure may be implemented in hardware, or any combination of software and hardware. Whether these aspects are implemented in hardware or software depends upon the particular application and design constraints imposed on the overall system. Those with ordinary skill in the art may implement the described functionality in varying ways for each particular application, but such implementation decisions should not be interpreted as causing a departure from the scope of the invention. The foregoing description is provided to enable any person skilled in the art to fully understand the scope of the invention. Modifications to various aspects disclosed herein will be readily apparent to those skilled in the art. Accordingly, the scope of the claims will not be limited to the various exemplary embodiments provided herein. No claim element is to be construed under the provisions of 35 U.S.C. §112(f), unless the element is expressly recited using the phrase “means for” or, in the case of a method claim, the element is recited using the phrase “step for.” The claims are not intended to be limited to the various aspects of this disclosure, but are to be accorded the full scope consistent with the language of the claims. All structural and functional equivalents to the various components of the exemplary embodiments described throughout this disclosure that are known to those of ordinary skill in the art are expressly incorporated herein by reference and are intended to be encompassed by the claims.

What is claimed is:

1. A circuit, comprising:
a pulse generator; and
a latch having an output configured to trigger the pulse generator, wherein the latch is configured to be set by an input signal and reset by feedback from the pulse generator.

2. The circuit of claim 1, further comprising:
a timer configured to have a timed output that is triggered by the pulse generator, wherein the timer is further configured to reset the pulse generator at an end of the timed output.

3. The circuit of claim 2, further comprising:
a replica circuit comprising the pulse generator and the latch; and
an access circuit configured to generate an output for asserting a word line to provide access to one or more memory cells in response to the input signal and for de-asserting the word line in response to the end of the timed output from the timer.

4. The circuit of claim 3, wherein the access circuit comprises a read circuit configured to generate a read clock used to read data from the one or more memory cells.

5. The circuit of claim 3, wherein the access circuit comprises a write circuit configured to generate a write clock used to write data to the one or more memory cells.

6. The circuit of claim 3, wherein the access circuit comprises:
a second pulse generator configured to generate an output for controlling the word line; and
a second latch configured to trigger the second pulse generator, wherein the second latch is configured to be set by the input signal and reset by feedback from the second pulse generator.

7. The circuit of claim 1, further comprising:
a read circuit comprising the pulse generator and the latch, wherein the pulse generator is configured to generate an output for controlling a read word line to access one or more memory cells.

8. The circuit of claim 1, further comprising:
a write circuit having the pulse generator and the latch, wherein the pulse generator is configured to generate an output for controlling a write word line to access one or more memory cells.

9. The circuit of claim 1, wherein the pulse generator is configured to receive the output from the latch and to output the feedback that resets the latch.

10. The circuit of claim 9, wherein the feedback that resets the latch is output by the pulse generator after a delay that is based on dissipating a charge at a node in the pulse generator.

11. A method of generating a pulse, the method comprising:
setting a latch using an input signal;
triggering a pulse generator in response to the latch being set; and
resetting the latch using feedback from the pulse generator.

12. The method of claim 11, further comprising:
resetting the pulse generator at an end of a timed output that is generated by a timer and triggered by the pulse generator.

13. The method of claim 12, further comprising:
generating an output for asserting a word line using an access circuit to provide access to one or more memory cells and for de-asserting the word line at the end of the timed output from the timer, wherein the pulse generator and the latch are included in a replica circuit.

14. The method of claim 13, wherein the access circuit comprises a read circuit configured to generate a read clock used to read data from the one or more memory cells.

15. The method of claim 13, wherein the access circuit comprises a write circuit configured to generate a write clock used to write data to the one or more memory cells.

16. The method of claim 13, further comprising:
generating an output for controlling the word line using a second pulse generator of the access circuit; and
triggering the second pulse generator using a second latch that is configured to be set by the input signal and reset by feedback from the second pulse generator.

17. The method of claim 11, further comprising:
generating an output using the pulse generator for controlling a word line to access one or more memory cells,
wherein the pulse generator and the latch are included in a read circuit configured to generate a read clock used to read data from the one or more memory cells.

18. The method of claim 11, further comprising:
generating an output using the pulse generator for controlling a word line to access one or more memory cells,
wherein the pulse generator and the latch are included in a write circuit configured to generate a write clock used to write data to the one or more memory cells.

19. The method of claim 11, wherein the triggering the pulse generator comprises providing an output by the latch and receiving the output by the pulse generator.

20. The method of claim 19, wherein the resetting the latch comprises outputting feedback by the pulse generator and receiving the feedback by the latch.

21. The method of claim 20, wherein the feedback that resets the latch is output by the pulse generator after a delay that is based on dissipating a charge at a node in the pulse generator.

22. A circuit, comprising:
generating means for generating a pulse; and
triggering means for triggering the generating means, wherein the triggering means is configured to be set by an input signal and reset by feedback from the generating means.

23. The circuit of claim 22, further comprising:
timer means for resetting the generating means, wherein the timer means is configured to have a timed output that is triggered by the generating means and further configured to reset the generating means at an end of the timed output.

24. The circuit of claim 23, further comprising:
a replica circuit comprising the generating means and the triggering means; and
an access circuit configured to generate an output for asserting a word line to provide access to one or more memory cells in response to the input signal and for de-asserting the word line at the end of the timed output from the timer means.

25. The circuit of claim 24, wherein the access circuit comprises a read circuit configured to generate a read clock used to read data from the one or more memory cells.

26. The circuit of claim 24, wherein the access circuit comprises a write circuit configured to generate a write clock used to write data to the one or more memory cells.

27. The circuit of claim 24, wherein the access circuit comprises:
second generating means for generating an output to control the word line; and
second triggering means for triggering the second generating means, wherein the second triggering means is set by the input signal and reset by feedback from the second generating means.

28. The circuit of claim 22, further comprising:
a read circuit comprising the generating means and the triggering means, wherein the generating means is configured to generate an output for controlling a read word line to access one or more memory cells.

29. The circuit of claim 22, further comprising:
a write circuit comprising the generating means and the triggering means, wherein the generating means is configured to generate an output for controlling a write word line to access one or more memory cells.

30. The circuit of claim 22, wherein the generating means is further for receiving the output from the triggering means and outputting the feedback that resets the triggering means.

31. The circuit of claim 30, wherein the feedback that resets the triggering means is output by the generating means after a delay that is based on dissipating a charge at a node in the generating means.
